(19) United States
(12) Patent Application Publication
(10) Pub. No.: US 2013/0153536 A1
(43) Pub. Date: Jun. 20, 2013

(54) COMBINATORIAL PROCESSING USING A REMOTE PLASMA SOURCE

(71) Applicants: ShouQian Shao, Fremont, CA (US); Kent Riley Child, Dublin, CA (US); Danny Wang, Saratoga, CA (US)

(72) Inventors: ShouQian Shao, Fremont, CA (US); Kent Riley Child, Dublin, CA (US); Danny Wang, Saratoga, CA (US)

(73) Assignee: Intermolecular, Inc., San Jose, CA (US)

(21) Appl. No.: 13/328,129

(22) Filed: Dec. 16, 2011

(51) Int. Cl. B44C 1/22; H05H 1/24; B08B 5/00; C23C 16/50

(52) U.S. Cl. 216/59; 118/720; 156/345.29; 216/67; 427/569; 134/1.1

(57) ABSTRACT

Methods and apparatuses for combinatorial processing using a remote plasma source are disclosed. The apparatus includes a remote plasma source and an inner chamber enclosing a substrate support. An aperture is operable to provide plasma exposure to a site-isolated region on a substrate. A transport system moves the substrate support and is capable of positioning the substrate such that the site-isolated region can be located anywhere on the substrate. Barriers and a gas purge system operate to provide site-isolation. Plasma exposure parameters can be varied in a combinatorial manner. Such parameters include source gases for the plasma generator, plasma filtering parameters, exposure time, gas flow rate, frequency, plasma generator power, plasma generation method, chamber pressure, substrate temperature, distance between plasma source and substrate, substrate bias voltage, or combinations thereof.

### FIELD OF THE INVENTION

One or more embodiments of the present invention relate to methods and apparatuses for combinatorial processing using a remote plasma source for surface treatment and layer formation.

### BACKGROUND

Plasmas are widely used for a variety of treatment and layer deposition tasks in semiconductor fabrication. These applications include subtractive processes such as wafer precleaning, contaminant removal, native oxide removal, photoresist removal, plasma etching, as well as additive processes such as oxidation, nitridation, or hydridation of a layer both during and after formation. “Remote” plasma sources are frequently used, where the plasma generator is located at some distance from the surface to be treated or substrate on which a layer is being formed. The distance allows some filtering of the charged particles in the plasma. For example, the density of electrons and ions can be adjusted or filtered out from the generated plasma.

Heretofore, remote plasma sources have been used to provide uniform exposure for entire substrates such as entire substrates, and experimental studies of process variables have required dedicating an entire wafer to each process condition to be tested. What is needed is a system that allows systematic exploration of process variables in a combinatorial manner with many variations on a single substrate.

### SUMMARY OF THE INVENTION

Methods and apparatuses for combinatorial processing using a remote plasma source are disclosed. The apparatus comprises an outer chamber, a remote plasma source and an inner chamber enclosing a substrate support. The inner chamber has a top surface parallel to the surface of the substrate support, a bottom surface parallel to the top surface and disposed below the substrate support, and one or more side walls. An aperture is disposed in the top surface of the inner chamber and is operable to provide site-isolated exposure of plasma from the remote plasma source to a site-isolated region on a substrate. The aperture is disposed between the remote plasma source and the substrate and has an area less than that of the substrate. A barrier can be positioned near the edges of the aperture, extending down from the top surface of the inner chamber toward the substrate, and separated from the substrate by a small gap, typically less than about 0.5 mm. The barrier can define the boundaries of the site isolated region on the substrate. A gas purge system can be provided from a plurality of flow outlets at the edge of the substrate support. The gas purge system can provide a gas flow into the site-isolated region through the small gap and out of the site-isolated region through the aperture. A substrate heater can be mounted in the substrate support. A transport system moves the substrate support and is capable of positioning the substrate such that the site-isolated region can be located anywhere on the substrate.

Methods of surface exposure to a plasma or reactive radical species are provided. The methods comprise exposing a first site-isolated region of a surface of a substrate to a plasma or reactive radical species from a remote plasma source under a first set of process parameters, exposing a second site-isolated region of the surface of the substrate to a plasma or reactive radicals from a remote plasma source under a second set of process parameters, and varying the first set and second set of process parameters in a combinatorial manner. The first set and second set of process parameters include source gases for the plasma generator, plasma filtering parameters, exposure time, gas flow rate, frequency, plasma generator power, plasma generation method, chamber pressure, substrate temperature, distance between plasma source and substrate, substrate bias voltage, or combinations thereof. The exposing can be controlled by an aperture in a plate disposed between the remote plasma source and the substrate. The aperture has an area less than that of the substrate. The exposing can be further controlled by placing a barrier near the edges of the aperture, wherein the barrier extends from the aperture plate to the substrate surface and is separated by a small gap from the substrate surface. The exposing can also be controlled by a gas purge system that provides a flow of gas into the site-isolated region through the small gap and out of the site-isolated region through the aperture.

The method can be extended by exposing a third site-isolated region of the substrate to a plasma or reactive radical species from a remote plasma source under a third set of process parameters, and more generally, by exposing a plurality of site-isolated regions of the substrate to a plasma or reactive radical species from a remote plasma source under a plurality of different sets of process parameters. The substrate can be analyzed to evaluate the effect of the different process parameters on the substrate. Plasma exposure process parameters can be varied in a combinatorial manner. Plasma exposure process parameters include source gases for the plasma generator, plasma filtering parameters, exposure time, gas flow rate, frequency, plasma generator power, plasma generation method, chamber pressure, substrate temperature, distance between plasma source and substrate, substrate bias voltage, or combinations thereof.

### BRIEF DESCRIPTION OF THE DRAWINGS

FIG. 1 is a schematic diagram for implementing combinatorial processing and evaluation.

FIG. 2 is a schematic diagram for illustrating various process sequences using combinatorial processing and evaluation.

FIG. 3 shows an illustrative embodiment of an apparatus enabling combinatorial processing using a remote plasma source.

### DETAILED DESCRIPTION

Before the present invention is described in detail, it is to be understood that unless otherwise indicated this invention is not limited to specific layer compositions or surface treatments. It is also to be understood that the terminology used herein is for the purpose of describing particular embodiments only and is not intended to limit the scope of the present invention.

It must be noted that as used herein and in the claims, the singular forms “a,” “and” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. The term “about” generally refers to ±10% of a stated value.

### DEFINITIONS

The term “site-isolated” as used herein refers to providing distinct processing conditions, such as controlled temperature, flow rates, chamber pressure, processing time, plasma composition, and plasma energies. Site isolation may provide complete isolation between regions or relative isolation between regions. Preferably, the relative isolation is sufficient to provide a control over processing conditions within ±10%, within ±5%, within ±2%, within ±1%, or within ±0.1% of the target conditions. Where one region is processed at a time, adjacent regions are generally protected from any exposure that would alter the substrate surface in a measurable way.

The term “site-isolated region” is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

The term “substrate” as used herein may refer to any workpiece on which formation or treatment of material layers is desired. Substrates may include, without limitation, silicon, silica, sapphire, zinc oxide, SiC, AlN, GaN, Spinel, coated silicon, silicon on oxide, silicon carbide on oxide, glass, gallium nitride, indium nitride and aluminum nitride, and combinations (or alloys) thereof. The term “substrate” or “wafer” may be used interchangeably herein. Semiconductor wafer shapes and sizes can vary and include commonly used round wafers of 2″, 4″, 200 mm, or 300 mm in diameter.

The term “remote plasma source” as used herein refers to a plasma generator (e.g., an rf or microwave plasma generator) located at a distance from a deposition or treatment location sufficient to allow some filtering of the plasma components. For example, the density of ions and electrons can be adjusted by distance, and electrons and ions can also be filtered out using suitable electrode configurations, such as a grounded metal showerhead so that only atomic or molecular radicals reach the substrate.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

The present invention is described in one or more embodiments in the following description with reference to the Figures, in which like numerals represent the same or similar elements. While the invention is described in exemplary terms which include a best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Embodiments of the present invention provide a system for systematic exploration of plasma treatment process variables in a combinatorial manner with the possibility of performing many variations on a single substrate. The combinatorial processing permits a single substrate to be systematically explored using different plasma processing conditions, and reduces or eliminates variables that interfere with research quality. The apparatuses and methods disclosed herein permit the systematic exploration of plasma treatments on a single substrate using combinatorial methods, and removes the run to run variability and inconsistencies between substrates that hamper research and optimization of process variables.

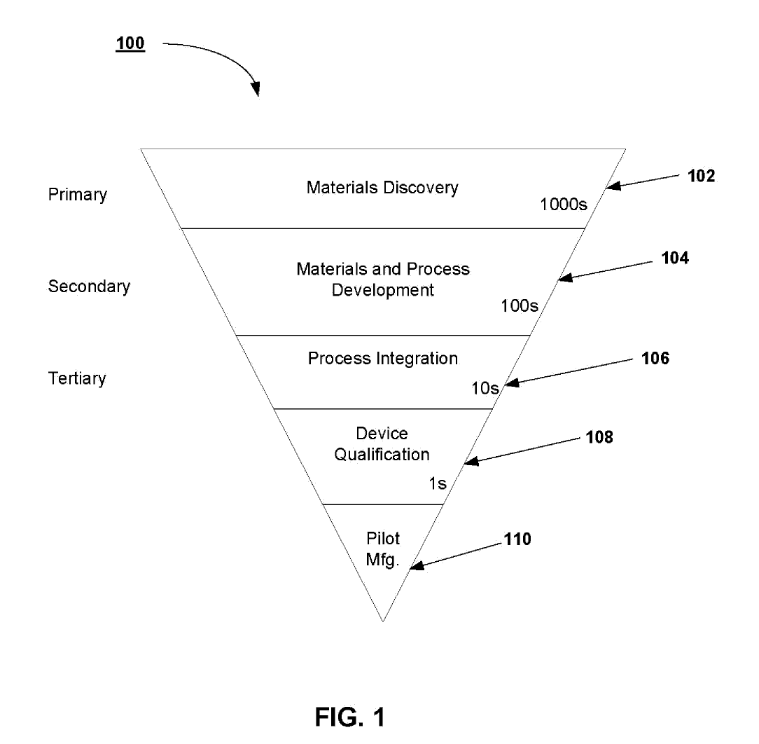

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage,

102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention.

While the combinatorial processing varies certain materials, hardware details, or process sequences, the composition or thickness of the layers or structures or the actions, such as cleaning, surface preparation, deposition, surface treatment, etc. is substantially uniform through each discrete region. Furthermore, while different materials or processes may be used for corresponding layers or steps in the formation of a structure in different regions of the substrate during the combinatorial processing, the application of each layer or use of a given process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

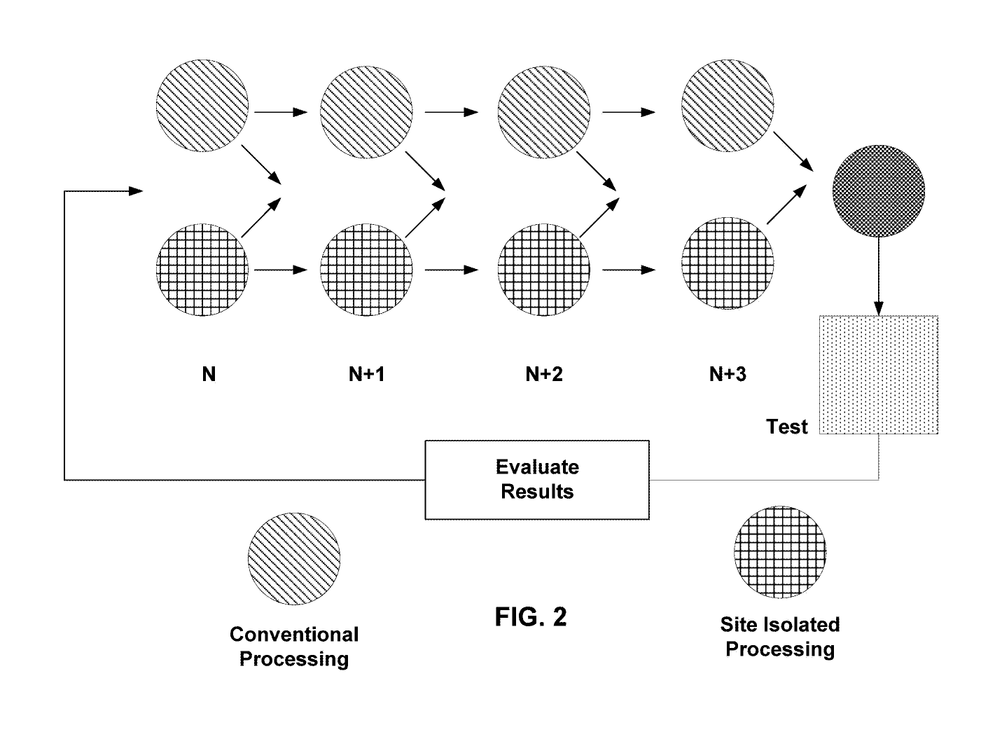

FIG. 2 is a simplified schematic diagram illustrating a general methodology for combinatorial process sequence integration that includes site-isolated processing and/or conventional processing in accordance with one embodiment of the invention. In one embodiment, the substrate is initially processed using conventional process N. In one exemplary embodiment, the substrate is then processed using site-isolated process N+1. During site-isolated processing, an HPC module may be used, such as the HPC module described in U.S. patent application Ser. No. 11/352,077 filed on Feb. 10, 2006. The substrate can then be processed using site-isolated process N+2, and thereafter processed using conventional process N+3. Testing is performed and the results are evaluated. The testing can include physical, chemical, acoustic, magnetic, electrical, optical, etc. tests. From this evaluation, a particular process from the various site-isolated processes (e.g. from steps N+1 and N+2) may be selected and fixed so that additional combinatorial process sequence integration may be performed using site-isolated processing for either process N or N+3. For example, a next process sequence can include processing the substrate using site-isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above process flows can be applied to entire monolithic substrates, or portions of the monolithic substrates.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, the order in which materials are deposited, hardware details of the gas distribution assembly, etc. It should be appreciated that these process parameters are exemplary and not meant to be an exhaustive list as other process parameters commonly used with remote plasma exposure systems may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Substrates may be a conventional round 200 mm, 300 mm, or any other larger or smaller substrate/wafer size. In other embodiments, substrates may be square, rectangular, or other shape. One skilled in the art will appreciate that substrate may be a blanket substrate, a coupon (e.g., partial wafer), or even a patterned substrate having predefined regions. In another embodiments, a substrate may have regions defined through the processing described herein.

Software is provided to control the process parameters for each wafer for the combinatorial processing. The process parameters comprise selection of one or more source gases for the plasma generator, plasma filtering parameters, exposure time, substrate temperature, power, frequency, plasma generation method, substrate bias, pressure, gas flow, or combinations thereof.

Plasmas are widely used for a variety of treatment and layer deposition tasks in semiconductor fabrication. These applications include subtractive processes such as wafer precleaning, contaminant removal, native oxide removal, photoresist removal, as well as additive processes such as oxidation, nitridation, or hydridation of a layer both during and after formation. “Remote” plasma sources are frequently used, where the plasma generator is located at some distance from the surface to be treated or substrate on which a layer is to be formed. The distance allows some adjusting of the charged particles in the plasma. For example, the density of ions and electrons can be adjusted by distance, the electrons and ions can be filtered out from the generated plasma using suitable electrode configurations such as a grounded metal showerhead, so that, for example, only atomic radicals and molecule radicals (but not ions) reach the substrate.

The plasma generator for a remote plasma source can use any known means of pumping energy into atoms or molecules to ionize them and create a plasma. The energy source can be, for example, electromagnetic energy such as microwaves or other radio frequency energy or lasers.

Prior art systems using remote plasma sources were designed to treat the entire area of a substrate such as a 300 mm wafer. Combinatorial processing is difficult and expensive when the entire area of a substrate can only receive a single process variation. Embodiments of the present invention overcome this limitation by providing a remote plasma source, an associated substrate positioning system, and a site isolation system that allows a selected region of a substrate to be processed while the remaining regions of the substrate are protected from exposure to the plasma and reactive radical species unless or until such exposure is intended.

Accordingly, an apparatus for combinatorial processing using remote plasma exposure of a substrate is disclosed. The apparatus comprises an outer chamber containing: a remote plasma source, an aperture allowing exposure of a site-isolated region of the substrate to plasma from the remote plasma source, and a transport system comprising a substrate support and capable of positioning the substrate such that the site-isolated region can be located anywhere on the substrate. The aperture has an area less than that of the substrate, so that a plurality of regions on a single substrate can be exposed to plasma processing conditions. A barrier or barriers and a gas purge system operate to provide exposure to plasma and reactive radical species within the site-isolated region, preventing exposure of regions of the substrate outside the area exposed to plasma and reactive radical species through the aperture. The plasma exposure process parameters can be varied in a combinatorial manner. The plasma exposure process parameters comprise source gases for the plasma generator, plasma filtering parameters, exposure time, gas flow rate, frequency, plasma generator power, plasma generation method, chamber pressure, substrate temperature, distance between plasma source and substrate, substrate bias voltage, or combinations thereof.

In some embodiments, the apparatus further comprises an inner chamber, contained within the outer chamber and enclosing the substrate and the substrate support. A “process kit” can be defined comprising the inner chamber, substrate, and substrate support. The inner chamber comprises a top surface parallel to and in close proximity to the substrate, a bottom surface below the substrate support, and one or more side walls. The dimensions of the inner chamber parallel to the substrate are such that any desired region on the substrate can be positioned under the aperture, i.e., there is sufficient space available in the inner chamber to accommodate the substrate and substrate support in any configuration necessary to provide access to the substrate through the aperture.

The aperture is preferably located in the top surface of the inner chamber with the barrier positioned near the edges of the aperture. The barrier can extend down from the top surface of the inner chamber toward the substrate, to provide more restriction to the flow of plasma and/or reactive radical species toward the remaining regions of the substrate. The barrier can be separated from the substrate by a small gap. The gap between the barrier and the substrate can be set to a distance of about 0.5 mm or less to exclude plasma and reactive radical species from reaching areas of the substrate outside the aperture and barrier. In some embodiments, the substrate support can comprise a substrate heater mounted in the substrate support for providing an independent temperature regulation as a process parameter that can be varied in a combinatorial manner.

The apparatus can include a gas purge system that comprises a plurality of flow outlets located at the edge of the substrate support. The gas purge system provides a gas flow into the site-isolated region through the small gap between the barrier and the substrate and out of the site-isolated region through the aperture, preventing plasma and/or reactive radical species from leaking past the barrier and affecting the protected regions of the substrate. The barrier or barriers and gas purge system can work together with the aperture to control exposure of plasma and reactive radical species to the substrate surface.

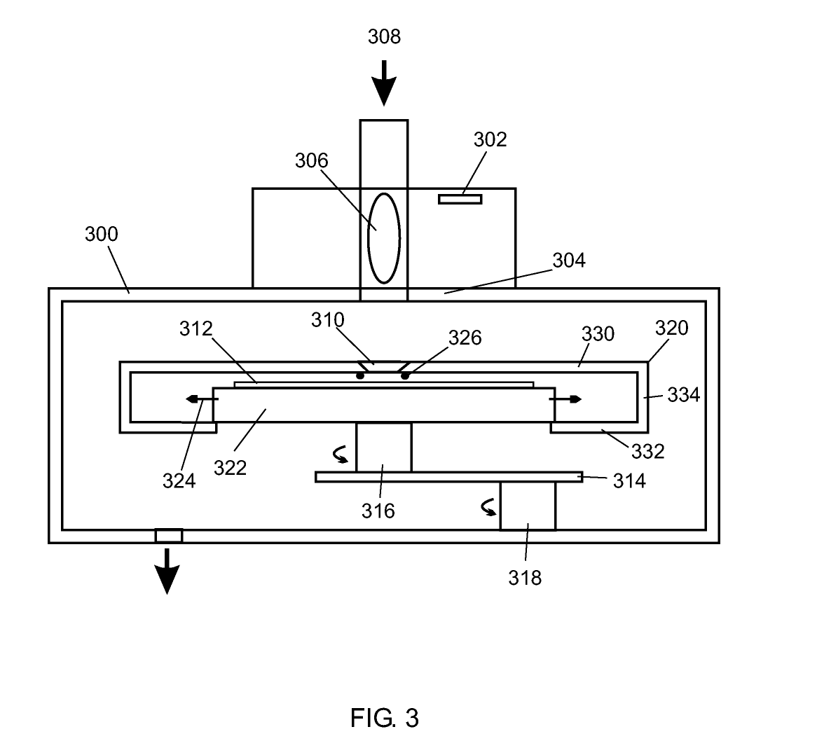

FIG. 3 illustrates the overall layout of some embodiments of a system enabling combinatorial processing using a remote plasma source. An outer process chamber 300 is provided. A remote plasma source 302 is mounted on a chamber lid 304 either directly as illustrated or through a short flange. The plasma 306 is entrained into a central gas flow 308 which is directed toward an aperture 310. The aperture is in close proximity to a substrate 312. A substrate positioning system 314 can position any region on the substrate 312 directly under the aperture 310. As illustrated in FIG. 3, the substrate positioning system can provide two displaced axes of rotation 316 and 318. The two-axis rotation configuration illustrated can provide 360° of rotation for the upper rotation (providing an angular coordinate) and 60° of rotation for the lower axis (approximating a radial coordinate) to provide all possible substrate positions. Alternatively, other positioning systems such as X-Y translators can also be used. In addition, substrate support 322 may move in a vertical direction. It should be appreciated that the rotation and movement in the vertical direction may be achieved through known drive mechanisms which include magnetic drives, linear drives, worm screws, lead screws, a differentially pumped rotary feed through drive, etc.

An inner chamber (also called a “process kit”) 320 provides an enclosure for the substrate 312 and the substrate support 322. Substrate support 322 can be configured to hold a substrate 312 thereon, and can be any known substrate support, including but not limited to a vacuum chuck, electrostatic chuck or other known mechanisms. The shape can be selected to conveniently enclose the substrate and substrate support in all positions used; for example, it can be cylindrical. The inner chamber 320 comprises a top surface 330 parallel to the substrate 312, a bottom surface 332 below the substrate support 322, and one or more side walls 334. The top surface 330 need not be positioned close the substrate surface. The substrate 312 is shown mounted on substrate support 322. The inner chamber 320 is typically made from a material such as quartz or ceramic that is mechanically and chemically stable at process temperatures. The inner chamber (or process kit) 320 can be made of two different materials, with a center portion made of quartz or ceramic, and the edge portion made of metal. The X-Y extent of the inner chamber 320 is large enough to accommodate the substrate 312 in any position that can be achieved using the substrate positioning system.

The substrate support 322 can include a substrate heater (e.g., resistive or inductive) and can be sized to be larger than the largest substrate to be processed. Substrate temperatures for most remote plasma applications are less than 500 C, although any suitable heater power and range of temperature control. The substrate support 322 can also be configured to provide a gas purge flow 324, for example from the edges of the support, using argon, helium, or any other gas that is not reactive under the process conditions.

The aperture 310 defines the area of a site-isolated region where exposure to a plasma occurs. Barrier 326 near the edges of the site-isolated region provides control over plasma exposure, and serves to restrict plasma or reactive radical species access to regions outside the area immediately under the aperture 310. The position, shape, and height of barrier 326 can be chosen to provide maximal protection of areas of the substrate 312 for which plasma exposure is not desired. Barrier 326 can be made from a high-temperature O-ring material such as KALREZ® fluoropolymer or a refractory material such as quartz or ceramic. In some embodiments, the barrier is circular; the barrier does not have to be any particular shape, but most generally is compatible with the shape of the aperture 310. The barrier 326 can be positioned with a small gap (typically less than 0.5 mm) to the substrate 312, and the gas purge flow 324 can be adjusted so that any gas leakage under the barrier 326 is directed into the site-isolated region and out through the aperture 310.

The aperture shape and size can be varied according to the needs of particular combinatorial experiments. Typical shapes are round, square, or rectangular with linear extents of about 10 to about 25 mm, although other shapes and sizes are possible, for example about 1 to about 65 mm. Further experimental design flexibility can be provided by using patterned apertures with multiple openings.

In some embodiments, methods of combinatorially varying surface exposure to a plasma or reactive radical species are provided. The methods comprise exposing a first site-isolated region of a substrate to a plasma or reactive radical species from a remote plasma source under a first set of process parameters, and exposing a second site-isolated region of the substrate to a plasma or reactive radical species from a remote plasma source under a second set of process parameters. During plasma exposure, the remaining area (the unexposed area) of the substrate is protected from exposure to the plasma or reactive radicals. The process parameters can be varied in a combinatorial manner. Typically, the process parameters comprise source gases for the plasma generator, plasma filtering parameters, exposure times, gas flow rates, frequencies, plasma generator powers, plasma generation methods, chamber pressures, substrate temperatures, distances between plasma source and substrate, substrate bias voltages, or combinations thereof.

The site-isolated region is exposed to a plasma or reactive radical species through an aperture in a top surface of an inner chamber. As shown in an embodiment in FIG. 3, the top surface is parallel to and in close proximity to the substrate.

The method can further comprise exposing a third site-isolated region of the substrate to a plasma or reactive radical species from a remote plasma source under a third set of process parameters. The exposing of site-isolated regions of the substrate to a plasma or reactive radical species under different process parameters can be repeated until the desired process parameters have been performed, i.e., by exposing a plurality of site-isolated regions of the substrate to a plasma or reactive radical species from a remote plasma source under a plurality of sets of process parameters. After a desired number of regions of the substrate have been exposed to plasma under different processing parameters, the substrate is analyzed to evaluate the effect of the different process parameters on the substrate.

Process times for exposure to remote plasmas can vary. Typical process times vary from a few seconds to a few minutes. In some embodiments, the process times are preferably set by turning the remote plasma generator on and off. In some embodiments, the plasma generator is left on, and a shutter can be opened to start exposure, and the shutter can be closed to stop exposure. The shutter can be located anywhere between the remote plasma source 302 and the aperture 310.

### Applications

Wafer precleaning, contaminant removal, and photoresist removal can be performed using an oxygen plasma from a remote plasma source. A typical HPC experiment for contaminant removal comprises treating selected areas of a substrate over a range of source gases for the plasma generator, plasma filtering parameters, exposure times, gas flow rates, frequencies, plasma generator powers, plasma generation methods, chamber pressures, substrate temperatures, distances between plasma source and substrate, substrate bias voltages, or combinations thereof.

Many materials such as silicon and many metals tend to form a native surface oxide when exposed at room temperature to standard atmospheric conditions. This native oxide can be removed using a fluorine or other halogen plasma source.

A typical HPC experiment for native oxide removal comprises treating selected areas of a substrate over a range of source gases for the plasma generator, plasma filtering parameters, exposure times, gas flow rates, frequencies, plasma generator powers, plasma generation methods, chamber pressures, substrate temperatures, distances between plasma source and substrate, substrate bias voltages, or combinations thereof.

Remote plasma sources can also be used for a variety of additive processes such as plasma-enhanced chemical vapor deposition (PECVD). Oxide layers can be created by exposing a layer on a substrate to an oxygen-containing plasma (oxidation). Nitride layers can be created by exposing a layer on a substrate to a nitrogen-containing plasma (nitridation). Hydrogen can be added to a layer on a substrate by exposing the layer to a hydrogen plasma (hydridation). Typical HPC experiments for such layer formation tasks comprise exposing selected areas of a substrate over a range of substrate temperatures, exposure times, chamber pressure, ion energies, gas flow rates, and choice of plasma type and plasma power. The remote plasma sources can be used for surface treatments that reduce roughness, enable atomic migration, cause surface annealing, etc. The treatment gases can include any of the above gases as well as NH₃.

It will be understood that the descriptions of one or more embodiments of the present invention do not limit the various alternative, modified and equivalent embodiments which may be included within the spirit and scope of the present invention as defined by the appended claims. Furthermore, in the detailed description above, numerous specific details are set forth to provide an understanding of various embodiments of the present invention. However, one or more embodiments of the present invention may be practiced without these specific details. In other instances, well known methods, procedures, and components have not been described in detail so as not to unnecessarily obscure aspects of the present embodiments.

What is claimed is:

1. An apparatus for remote plasma exposure of a substrate comprising
a first chamber;
a remote plasma source;
a second chamber enclosing a substrate support, wherein the second chamber comprises a top surface parallel to the surface of the substrate support, a bottom surface parallel to the top surface and disposed below the substrate support, and one or more side walls;
an aperture disposed in the top surface of the second chamber and operable to provide site-isolated exposure of plasma from the remote plasma source to a site-isolated region on a substrate, wherein the aperture is disposed between the remote plasma source and the substrate and has an area less than that of the substrate; and
a transport system comprising the substrate support and capable of positioning the substrate such that the site-isolated region can be located anywhere on the substrate;
wherein the remote plasma source, second chamber and the transport system are disposed within the first chamber.

2. The apparatus of claim 1, wherein plasma exposure process parameters can be varied in a combinatorial manner.

3. The apparatus of claim 2, wherein the plasma exposure process parameters comprise at least one of source gases for the plasma generator, plasma filtering parameters, exposure time, gas flow rate, frequency, plasma generator power, plasma generation method, chamber pressure, substrate temperature, distance between plasma source and substrate, substrate bias voltage, or combinations thereof.

4. The apparatus of claim 1, further comprising a barrier positioned near the edges of the aperture, extending down from the top surface of the second chamber toward the substrate, and separated from the substrate by a gap, wherein the gap is less than about 0.5 mm.

5. The apparatus of claim 4, wherein the barrier defines the boundaries of the site isolated region on the substrate.

6. The apparatus of claim 1, further comprising a substrate heater mounted in the substrate support.

7. The apparatus of claim 1, further comprising a gas purge system comprising a plurality of flow outlets at the edge of the substrate support.

8. The apparatus of claim 7, wherein the gas purge system provides a gas flow into the site-isolated region through the small gap and out of the site-isolated region through the aperture.

9. The apparatus of claim 1, further comprising a shutter disposed between the remote plasma source and the aperture.

10. A method of surface exposure to a plasma or reactive radical species comprising
exposing a first site-isolated region of a surface of a substrate to a plasma or reactive radical species from a remote plasma source under a first set of process parameters;
exposing a second site-isolated region of the surface of the substrate to a plasma or reactive radical species from a remote plasma source under a second set of process parameters; and
varying the first set and second set of process parameters in a combinatorial manner.

11. The method of claim 10, wherein the first set and second set of process parameters comprise at least one of source gases for the plasma generator, plasma filtering parameters, exposure time, gas flow rate, frequency, plasma generator power, plasma generation method, chamber pressure, substrate temperature, distance between plasma source and substrate, substrate bias voltage, or combinations thereof.

12. The method of claim 10, wherein the exposing is controlled by an aperture in a plate disposed between the remote plasma source and the substrate and wherein the aperture has an area less than that of the substrate.

13. The method of claim 10, wherein the exposing is further controlled by placing a barrier near the edges of the aperture, wherein the barrier extends from the aperture plate to the substrate surface and is separated by a gap from the substrate surface.

14. The method of claim 10, wherein the exposing is further controlled by a gas purge system that provides a flow of gas into the site-isolated region through the gap and out of the site-isolated region through the aperture.

15. The method of claim 10, further comprising exposing a third site-isolated region of the substrate to a plasma or reactive radical species from a remote plasma source under a third set of process parameters.

16. The method of claim 10, further comprising exposing a plurality of site-isolated regions of the substrate to a plasma or reactive radical species from a remote plasma source under a plurality of different sets of process parameters.

17. The method of claim 10, wherein the substrate is analyzed to evaluate the effect of the different process parameters on the substrate.

18. The method of claim 10, wherein a transport system comprising the substrate support is capable of positioning the substrate such that a site-isolated region can be located anywhere on the substrate.
